(19) United States
(12) Patent Application Publication
(10) Pub. No.: US 2026/0226624 A1
(43) Pub. Date: Aug. 6, 2026

(54) PEDESTALS AND SHOWERHEADS INCLUDING DUAL PLENUM AND BAFFLE ARRANGEMENTS

(71) Applicant: LAM RESEARCH CORPORATION, Fremont, CA (US)

(72) Inventors: Gnyanesh Tushar TRIVEDI, Beaverton, OR (US); Joshua Nathaniel Eric MAK, Beaverton, OR (US); James F. LEE, Casper, WY (US); Daniel BOATRIGHT, Estacada, OR (US)

(21) Appl. No.: 19/152,658

(22) PCT Filed: Jan. 31, 2024
(86) PCT No.: PCT/US2024/013724

§ 371 Date: Jul. 31, 2025

Related U.S. Application Data
(60) Provisional application No. 63/444,724, filed on Feb. 10, 2023.

(51) Int. Cl. C23C 16/455; C23C 16/44; C23C 16/458

(52) U.S. Cl. CPC C23C 16/45591; C23C 16/4402; C23C 16/45565; C23C 16/4583

(57) ABSTRACT

A pedestal includes a support shaft and a body. The support shaft includes a supply channel that receives a process fluid. The body includes layers that receive the process fluid, distribute the process fluid across the body, and direct the process fluid from the pedestal at a substrate being processed. The body includes a distribution layer that includes a first plenum and channels. The channels extend radially from the supply channel to the first plenum and supply the process fluid from the supply channel to the first plenum. The body further includes a baffle layer and a cross-drill layer. The baffle layer includes first passages extending from the first plenum to a second plenum. The cross-drill layer includes second passages and the second plenum. The first plenum, the first passages, and the second plenum trap particles and/or increase flow rate uniformity of the process fluid to the second passages.

### CROSS-REFERENCE TO RELATED APPLICATIONS

This application claims the benefit of U.S. Provisional Application No. 63/444,724, filed on Feb. 10, 2023. The entire disclosure of the application referenced above is incorporated herein by reference.

### FIELD

The present disclosure relates to gas distribution pedestals and showerheads of substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system may be used to perform deposition, etching and/or other treatment of substrates such as semiconductor wafers. During processing, a substrate is arranged on a substrate support in a processing chamber of the substrate processing system. Gas mixtures including one or more precursors are introduced into the processing chamber and plasma may be struck to activate chemical reactions.

Thin film layers can be deposited on a substrate using a deposition process, such as plasma-enhanced chemical vapor deposition (PECVD). PECVD includes introducing a gas (or vapor) precursor to a processing chamber. Other processing and cleaning gas may also be introduced. The gases can be delivered to the processing chamber via a gas distribution pedestal or showerhead. As an example, the substrate can be supported on a gas distribution pedestal and gases are received by the pedestal and distributed to a backside of the substrate for deposition of layers on the backside of the substrate. As another example, the substrate may be supported by a non-gas distribution pedestal and gas may be received at a showerhead. The showerhead then distributes the gas at and across the substrate for deposition of layers on the top surface of the substrate.

### SUMMARY

A pedestal is disclosed that includes a support shaft and a body. The support shaft includes a supply channel configured to receive a process fluid. The body includes layers configured to receive the process fluid from the supply channel and distribute the process fluid across the body and direct the process fluid from the pedestal at a substrate being processed. The body includes a distribution layer. The distribution layer includes a plenum and channels. The channels extend from the supply channel to the plenum. Each respective channel of the channels is configured to decrease flow velocity radially along the respective channel, such that a first flow velocity at an inlet of the respective channel is greater than a second flow velocity at an outlet of the respective channel.

In other features, an overall cross-sectional flow area of the channels increases radially, such that a first overall cross-sectional flow area of the inlets of the channels is less than a second overall cross-sectional flow area of the outlets of the channels.

In other features, each respective channel of the channels increases radially in inner diameter. In other features, each channel of the channels diverts a portion of the process fluid to at least one adjacent channel. The at least one adjacent channel outputs the portion of the process fluid to the plenum.

In other features, each channel of the channels includes a first portion having a first inner diameter and a second portion having a second inner diameter. The second inner diameter being larger than the first inner diameter.

In other features, each channel of the channels diverts the portion of fluid to two adjacent channels. In other features, each of the two adjacent channels cross-through one of the other adjacent channels.

In other features, each flow path from the supply channel to the plenum includes an inlet of a respective channel of the channels and five outlets including an outlet of the respective channel and four outlets of adjacent channels receiving fluid from the respective channel. In other features, normalized volumetric flow rates at outlets of the channels are the same or within a predetermined percentage of each other.

In other features, the distribution layer includes a pair of branches that extend from each of the channels, such that a portion of each of the channels and the corresponding pair of branches are in a “Y”-shaped configuration.

In other features, normalized volumetric flow rates of outputs of the pairs of branches are the same or within a predetermined percentage of each other. In other features, the normalized volumetric flow rates of outputs of each of the channels and outputs of each of the branches are the same or within a predetermined percentage of each other.

In other features, at least one of i) mass output flow rates of the channels are the same or within a predetermined percentage of each other, and ii) volumetric output flow rates of the channels are the same or within a predetermined percentage of each other.

In other features, the distribution layer includes spreading junctions and cross-over junctions. Each of the channels diverts gas to two adjacent channels. The cross-over junctions where each the two adjacent channels of each of the channels crosses through and is fluidically coupled to two of the other adjacent channels. In other features, mass output flow rates of the two adjacent channels of each of the channels are the same or within a predetermined percentage of each other.

In other features, a pedestal is disclosed and includes a support shaft and a body. The support shaft includes a supply channel configured to receive a process fluid. The body includes layers configured to receive the process fluid from the supply channel and distribute the process fluid across the body and direct the process fluid from the pedestal at a substrate being processed. The body includes a distribution layer. The distribution layer includes a plenum and first channels. The first channels extend from the supply channel to the plenum. Each channel of the first channels divert a portion of the process fluid to one or more of second channels. The second channels extend from the first channels to the plenum.

In other features, each respective channel of the first channels is configured to decrease flow velocity radially along the respective channel, such that a first flow velocity at an inlet of the respective channel is greater than a second flow velocity at an outlet of the respective channel.

In other features, an overall cross-sectional flow area of the first channels increases radially, such that a first overall cross-sectional flow area of the inlets of the first channels is less than a second overall cross-sectional flow area of the outlets of the channels.

In other features, a showerhead is disclosed and includes a stem and a body. The stem includes a supply channel configured to receive a process fluid. The body includes layers configured to receive the process fluid from the supply channel and distribute the process fluid across the body and direct the process fluid from the showerhead at a substrate being processed. The body includes a distribution layer. The distribution layer includes a plenum and channels. The channels extend from the supply channel to the plenum. Each respective channel of the channels is configured to decrease flow velocity radially along the respective channel, such that a first flow velocity at an inlet of the respective channel is greater than a second flow velocity at an outlet of the respective channel.

In other features, a showerhead is disclosed and includes a stem and a body. The stem includes a supply channel configured to receive a process fluid. The body includes layers configured to receive the process fluid from the supply channel and distribute the process fluid across the body and direct the process fluid from the showerhead at a substrate being processed. The body includes a distribution layer. The distribution layer includes a plenum and first channels extending from the supply channel to the plenum. Each channel of the first channels diverts a portion of the process fluid to one or more of second channels. The second channels extend from the first channels to the plenum.

In other features, a pedestal is disclosed and includes a support shaft and a body. The support shaft includes a supply channel configured to receive a process fluid. The body includes layers configured to receive the process fluid from the supply channel and distribute the process fluid across the body and direct the process fluid from the pedestal at a substrate being processed. The body includes a distribution layer that includes a first plenum and channels. The channels extend radially from the supply channel to the first plenum and supply the process fluid from the supply channel to the first plenum. The body further includes a baffle layer and a cross-drill layer. The baffle layer includes first passages extending from the first plenum to a second plenum. The cross-drill layer includes second passages and the second plenum. The first plenum, the first passages, and the second plenum are configured to at least one of i) trap particles, and ii) increase flow rate uniformity of the process fluid to the second passages.

In other features, the first plenum is ring-shaped. The first passages extend vertically from the first plenum to the second plenum. The second plenum is ring-shaped. In other features, the first passages are radially inward of a radially outermost wall of the first plenum.

In other features, the first plenum includes recesses annularly in alignment with outlets of the channels. In other features, the channels include main channels and branches extending from the main channels to the first plenum. Outlets of the main channels and outlets of the branches are annularly in alignment respectively with the recesses.

In other features, a cross-sectional width of each of the first passages, measured radially, is smaller than a radially width of the first plenum and a radial width of the second plenum, which are also measured radially.

In other features, the first passages are annularly offset from outputs of the channels. In other features, the process fluid changes flow direction six times subsequent to exiting the channels and prior to exiting the second plenum.

In other features, the cross-drill layer includes the second passages configured to receive the process fluid from the second plenum. In other features, the first passages extend vertically. The second passages extend horizontally across the cross-drill layer. In other features, the first plenum changes flow direction of the process fluid multiple times. The baffle layer changes flow direction of the process fluid multiple times.

In other features, radially outermost walls of the first passages are laterally aligned with an outermost wall of the second plenum. Radially outermost wall of the first plenum is radially outward of the outermost wall of the second plenum and the outermost walls of the first passages.

In other features, the distribution layer includes: a pair of channels that extend from each of the channels to the first plenum; and a total number of the first passages is equal to a sum of a total number of outputs of the channels and a total number of outputs of the pairs of channels that extend from each of the channels.

In other features, each respective channel of the channels is configured to decrease flow velocity radially along the respective channel, such that a first flow velocity at an inlet of the respective channel is greater than a second flow velocity at an outlet of the respective channel.

In other features, a showerhead is disclosed and includes a stem and a body. The stem includes a supply channel configured to receive a process fluid. The body includes layers configured to receive the process fluid from the supply channel and distribute the process fluid across the body and direct the process fluid from the showerhead at a substrate being processed. The body includes a distribution layer that includes a first plenum and channels extending radially from the supply channel to the first plenum and supplying the process fluid from the supply channel to the first plenum. The body further includes: a baffle layer including first passages extending from the first plenum to a second plenum; and a cross-drill layer including a second passages and the second plenum. The first plenum, the first passages, and the second plenum are configured to at least one of i) trap particles, and ii) increase flow rate uniformity of the process fluid to the second passages.

In other features, the first plenum is ring-shaped. The first passages extend vertically from the first plenum to the second plenum. The second plenum is ring-shaped.

In other features, the first passages are radially inward of a radially outermost wall of the first plenum. In other features, the first plenum includes recesses annularly in alignment with outlets of the channels.

In other features, the channels include main channels and branches extending from the main channels to the first plenum. Outlets of the main channels and outlets of the branches are annularly in alignment respectively with the recesses.

In other features, a cross-sectional width of each of the first passages, measured radially, is smaller than a radially width of the first plenum and a radial with of the second plenum, which are also measured radially.

In other features, the first passages are annularly offset from outputs of the channels. In other features, the process fluid changes flow direction six times subsequent to exiting the channels and prior to exiting the second plenum.

In other features, the cross-drill layer includes the second passages configured to receive the process fluid from the second plenum. In other features, the first passages extend vertically. The second passages extend horizontally across the cross-drill layer.

In other features, the first plenum changes flow direction of the process fluid multiple times. The baffle layer changes flow direction of the process fluid multiple times.

In other features, radially outermost walls of the first passages are laterally aligned with an outermost wall of the second plenum. Radially outermost wall of the first plenum is radially outward of the outermost wall of the second plenum and the outermost walls of the first passages.

In other features, the distribution layer includes: a pair of channels that extend from each of the channels to the first plenum; and a total number of the first passages is equal to a sum of a total number of outputs of the channels and a total number of outputs of the pairs of channels that extend from each of the channels.

In other features, each respective channel of the channels is configured to decrease flow velocity radially along the respective channel, such that a first flow velocity at an inlet of the respective channel is greater than a second flow velocity at an outlet of the respective channel.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system including a gas distribution pedestal having layers for gas distribution in accordance with the present disclosure;

FIG. 2 is a side cross-section view of a portion of the gas distribution pedestal of FIG. 1;

FIG. 3 is a top cross-sectional view of an example gas distribution layer of the gas distribution pedestal of FIG. 1;

FIG. 4 is a top cross-sectional view of an example baffle layer of the gas distribution pedestal of FIG. 1 shown above the gas distribution layer of FIG. 3;

FIG. 5 is a cross-sectional view of another example gas distribution layer in accordance with the present disclosure;

FIG. 6 is a cross-sectional view of another baffle layer in accordance with the present disclosure;

FIG. 7 is a cross-sectional view of an example cross-drilled layer of the gas distribution pedestal of FIG. 1;

FIG. 8 is a close-up perspective view of a portion of the example gas distribution layer of FIG. 2 in accordance with present disclosure;

FIG. 9 is a close-up perspective view of a portion of an outer wall of a plenum of a gas distribution layer illustrating depth of one of multiple recesses (or notches) of the outer wall in accordance with the present disclosure;

FIG. 10 is a side cross-sectional view of a processing chamber including a showerhead having layers for gas distribution in accordance with the present disclosure;

FIG. 11 is a side cross-section view of a portion of the showerhead of FIG. 10;

FIG. 12 is a plot of normalized standard deviation of volumetric flow rate versus angle between inner and outer spokes of a gas distribution layer in accordance with the present disclosure;

FIG. 13 is a top cross-sectional view of inner and outer spokes of a gas distribution layer in accordance with the present disclosure; and

FIG. 14 is a plot of normalized standard deviation of volumetric flow rate versus an inner diameter ratio of inner and outer spokes in accordance with the present disclosure.

In the drawings, reference numbers may be reused to identify similar and/or identical elements.

### DETAILED DESCRIPTION

A gas distribution pedestal may include a gas distribution layer, a cross-drilled layer, and an upper gas emission layer. The gas distribution layer can include gas distribution channels arranged in, for example, an 8-spoke or 12-spoke pattern. The gas distribution channels extend from a central vertically extending channel to an outer peripheral plenum. The outer peripheral plenum is ring-shaped. The gas is distributed at high-velocity from the center vertically extending channel to the outer peripheral plenum. The gas is directed from the outer peripheral plenum laterally to cross-drilled channels of the cross-drilled layer. The gas is then directed from the cross-drilled layer out holes in the upper gas emission layer to the backside of a substrate.

Backside particles can be an issue for backside deposition tools. High chamber temperatures often includes use of an aluminum (Al) pedestal that is cooled to prevent overheating and excessive particle generation. The spokes (or radially extending channels) of the gas distribution layer of the pedestal can entrain particles of aluminum fluoride (AlF₃) due to the high-flow velocities and interaction between nitrogen trifluoride (NF₃) gas and the aluminum of the gas distribution pedestal. The high-flow velocity imparts momentum on the particles, which can result in a signature pattern on the backside of the substrate. The signature pattern can be similar to the pattern of the spokes.

The examples set forth herein include gas distribution pedestals and showerheads including gas distribution layers having patterns of gas distribution channels. The gas distribution channels decrease in flow velocity radially from center supply channels of the gas distribution layers to outer peripheral plenums of the gas distribution layers. In an embodiment, the flow velocities of the gas distribution channels decrease while maintaining a same overall gas flow rate. For example, the overall flow rate at a center of a gas distribution layer is the same as the an overall flow rate out of gas distribution channels at an outer peripheral plenum of the gas distribution layer. The number of gas distribution channels and the inner diameters of the gas distribution channels also increase from the centers of the gas distribution layers to the outer peripheral plenums. This increases the overall cross-sectional flow area, which decreases the average flow velocity out of the gas distribution channels as compared to the average flow velocities at the centers of the gas distribution layers and inlets of the gas distribution channels.

The stated examples prevent occurrence of a particle “spoke” pattern on a substrate. The patterns provide increased flow uniformity out of gas distribution layers and as a result out of a gas distribution pedestal or showerhead. Flow balance is provided by the disclosed gas distribution channel patterns. The gas distribution patterns include equal spaced apart channels with symmetric patterns about both X and Y axes. The patterns include multiple expansion points and cross-over points for reduced flow velocities and equalizing of gas pressures in radially outermost channels. This provides a balanced flow structure for uniform flow output.

The examples minimize velocity of gas flow output by channels of gas distribution layers while providing arrangements with a decreased amount of channel inlets at center located gas supply channels. These arrangements are provided for both pedestal and showerhead configurations. In addition, these arrangements include multiple plenum and baffle arrangements for entrapping particles entrained in gas flowing through the channels. This prevents the particles from reaching a substrate being processed and thus prevents formation of a signature pattern on the substrate.

The examples provide uniform flow distribution, which is aided by multiple different aspects of the channel arrangements, including: channels with increasing inner diameters along the channels in a radial direction; multi-plenum baffle arrangements for changing flow direction of gas multiple times; channel spreading junctions with “Y”-shaped configurations; spreading junctions with selected diameter ratios between inner diameters of main spokes and inner diameters of branches off of the main spokes; and channel cross-over junctions. The “Y”-shaped configurations include “Y” branches the extend off of main spokes for decreased flow velocity in the main spokes. The diameter ratios are set for balanced mass flow rates in outlets of output channels of a corresponding gas distribution layer. The output channels refer to main channels and adjacent channels feeding gas to an outer peripheral plenum. Angles of the branches relative to main spokes are also set for balanced mass flow rates. Lengths of different portions of the main spokes, which have different inner diameters are also set for balanced mean velocities out of the output channels. The examples minimize flow velocity in the output channels and mass flow rate standard deviation among the output channels.

Although the following examples are primarily described with respect to gas flow, the examples apply to other fluids including processing liquids.

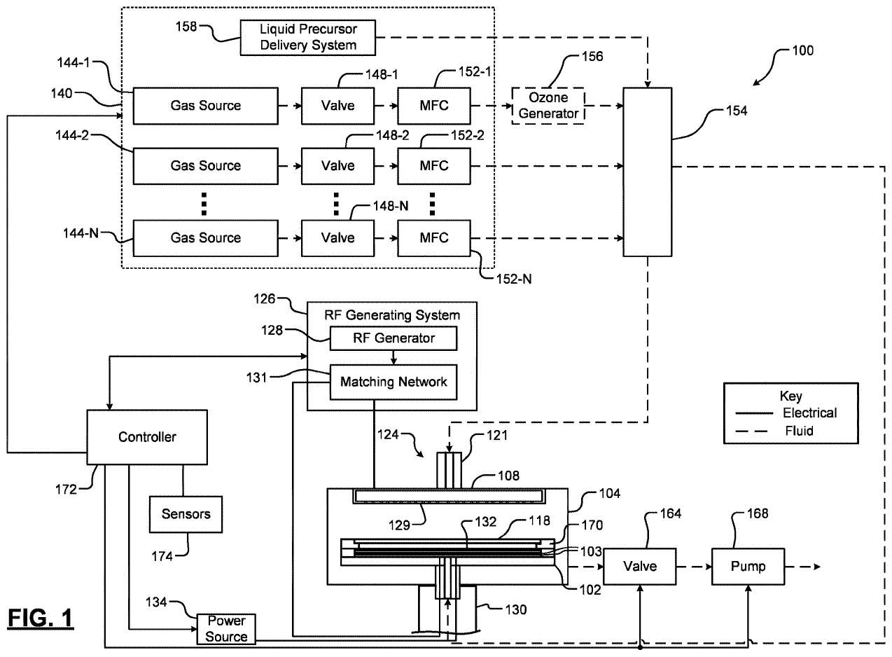

FIG. 1 shows an example substrate processing system 100 that includes a gas distribution pedestal (referred to as the pedestal) 102 having layers 103 for gas distribution. The example of FIG. 1 is applicable to PECVD chambers and other substrate processing chambers. The substrate processing system 100 includes a processing chamber 104 that encloses components of the substrate processing system 100. The substrate processing system 100 includes a first electrode 108 and a substrate support, such as the pedestal 102. The pedestal 102 may be implemented as or include a second electrode. As an example, the first electrode 108 may be an upper electrode and the second electrode may be a lower electrode. A substrate 118 is arranged on the pedestal 102 between the first electrode 108 and the second electrode during processing.

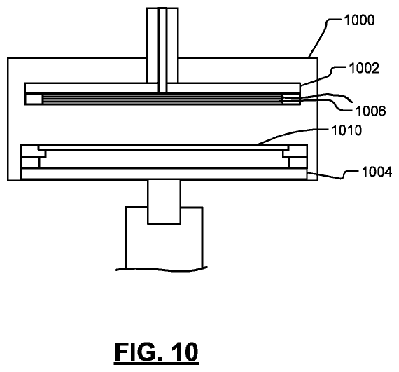

For example only, the first electrode 108 may include a showerhead 124 that may introduce and distributes process gases. The pedestal 102 may be implemented as a gas distribution pedestal, as shown and distribute gases to a backside (or bottom side) of the substrate 118. In an embodiment, the pedestal 102 distributes gases to the backside of the substrate 118 and the showerhead 124 does not distribute gases. In another embodiment, the showerhead 124 distributes gases to the front (or top) side of the substrate 118 and the pedestal does not distribute gases. In yet another embodiment, the showerhead 124 distributes gases to the top side of the substrate and the pedestal 102 distributes gases to the backside of the substrate 118. The showerhead 124 may be replaced with the showerhead of FIG. 10, which may be configured similarly as the pedestal 102, as further described below.

The showerhead 124 includes a stem 121 that may receive processing fluids and direct the processing fluids through the showerhead 124. The fluids are directed out holes in a faceplate 129 of the showerhead 124 and directed at the substrate 118. The pedestal 102 includes a support shaft 130 that may receive processing fluids and direct the processing fluids through the pedestal 102. The fluids are directed out holes in a top plate 132 of the pedestal 102 and directed at the substrate 118. The body of the pedestal 102 may be implemented as the second electrode. As an alternative, the second electrode may be a conductive electrode embedded within a non-conductive portion of the pedestal 102. As another alternative, the pedestal 102 may include a conductive plate that acts as the second electrode.

A radio frequency (RF) generating system 126 generates and outputs an RF voltage to the first electrode 108 and/or the second electrode when plasma is used. In some examples, one of the first electrode 108 and the second electrode may be DC grounded, AC grounded, or at a floating potential. For example only, the RF generating system 126 may comprise one or more RF voltage generators 128 (e.g., a capacitively-coupled plasma RF power generator, a bias RF power generator, and/or other RF power generator) such as an RF voltage generator 128 that generate RF voltages. The RF voltages are fed by one or more matching and distribution networks 131 to the second electrode and/or the first electrode 108. For example, as shown, the RF voltage generator 128 provides an RF and/or bias voltage to the second electrode. The second electrode may receive power alternatively or additionally from other power sources, such as a power source 134. In other examples, an RF voltage may be supplied to the first electrode 108 or the first electrode 108 may be connected to a ground reference.

An example gas delivery system 140 comprises one or more gas sources 144-1, 144-2, . . . , and 144-N (collectively gas sources 144), where N is an integer greater than zero. The gas sources 144 supply one or more gases (e.g., precursors, inert gases, etc.) and mixtures thereof. Vaporized precursor may also be used. At least one of the gas sources 144 may contain gases used in the pre-treatment process of the present disclosure (e.g., NH₃, N₂, etc.). The gas sources 144 are connected by valves 148-1, 148-2, . . . , and 148-N (collectively valves 148) and mass flow controllers 152-1, 152-2, . . . , and 152-N (collectively mass flow controllers 152) to a manifold 154. An output of the manifold 154 is fed to the processing chamber 104. For example only, the output of the manifold 154 is fed to the pedestal and/or the showerhead 124.

In some examples, an optional ozone generator 156 may be provided between the mass flow controllers 152 and the manifold 154. In some examples, the substrate processing system 100 may comprise a liquid precursor delivery system 158. The liquid precursor delivery system 158 may be incorporated within the gas delivery system 140 as shown or may be external to the gas delivery system 140. The liquid precursor delivery system 158 is configured to provide precursors that are liquid and/or solid at room temperature via a bubbler, direct liquid injection, vapor draw, etc.

A valve 164 and pump 168 may be used to evacuate reactants from the processing chamber 104. A controller 172 may be used to control various components of the substrate processing system 100. For example only, the controller 172 may be used to control flow of process, carrier, and precursor gases, striking and extinguishing plasma, removal of reactants, monitoring of chamber parameters, etc. The controller 172 may receive measurement signals indicative of process parameters, conditions within the processing chamber 104, etc. via one or more sensors 174 arranged throughout the substrate processing system 100.

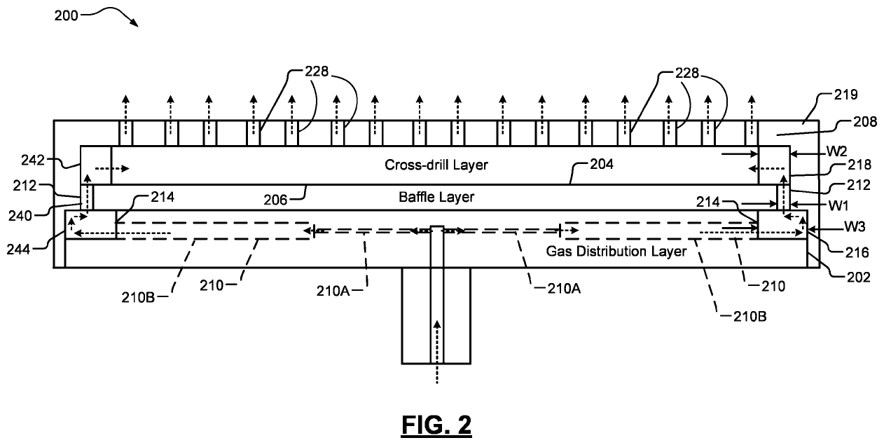

The pedestal 102 includes the layers 103, which may include a gas distribution layer (or plate), a baffle layer (or plate), a cross-drilled layer (or plate), and the top layer (or plate) 132. Examples of the gas distribution, baffle, and cross-drilled layers are shown in FIGS. 2-7. A ring 170 may support the substrate 118 above the top layer 132 to provide a gap between the backside of the substrate 118 and the top surface of the top layer 132.

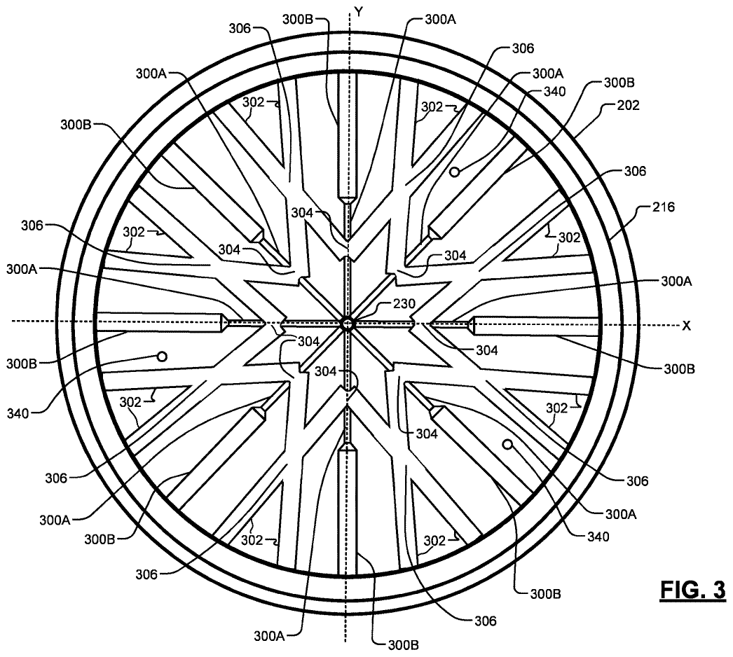

FIG. 2 shows a portion 200 of the gas distribution pedestal 102 of FIG. 1. The portion 200 includes a gas distribution layer 202, a baffle layer 204, a cross-drilled layer 206, and a top layer 208. The gas distribution layer 202 has a pattern of gas distribution channels (also referred to as “spokes”), some of which (designated channels 210) are shown with dashed lines to illustrate gas flow. The channels 210 are not annularly in line with vertical gas passages (two example passages 212 are shown in FIG. 2) in the baffle layer 204, as better shown in FIG. 3 and thus are shown with hidden lines.

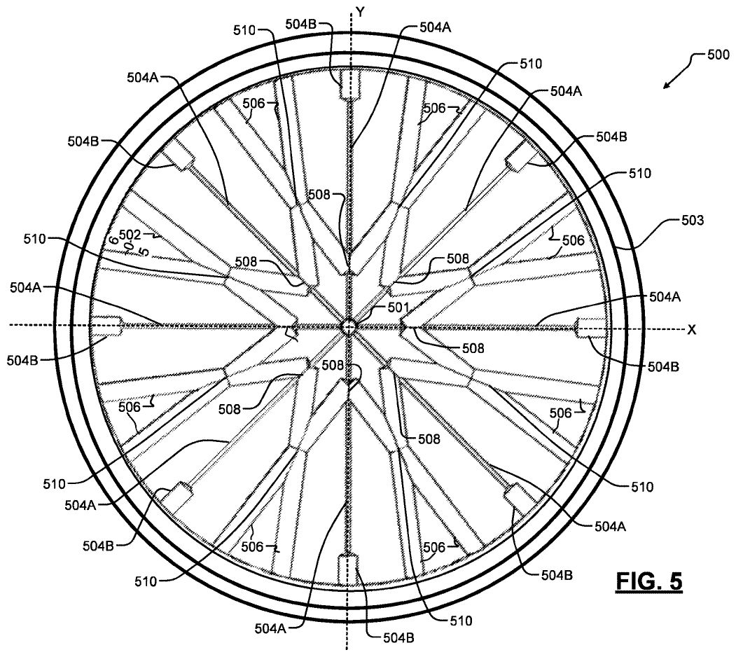

The gas distribution layer 202 includes a pattern of gas distribution channels, examples of which are shown in FIGS. 3 and 5. The gas distribution channels have radially decreasing flow velocities due to: increases in inner diameters of the channels; increases in the number of channels; and spreading of gas from a smaller number of channels to a larger number of channels. The structure of the gas distribution layer 202 equalizes pressures in the channels and uniformly distributes gas to outlets (e.g., outlets 214) of the channels. The outlets of the channels output gas to a first plenum 216. The plenum 216 is ring-shaped and distributes the gas to vertical passages (e.g., the passages 212) of the baffle layer 204. The vertical passages (also referred to as channels) are offset radially inward from an outermost portion (or recessed walls) of the first plenum 216 and offset annularly from the outlets of the channels.

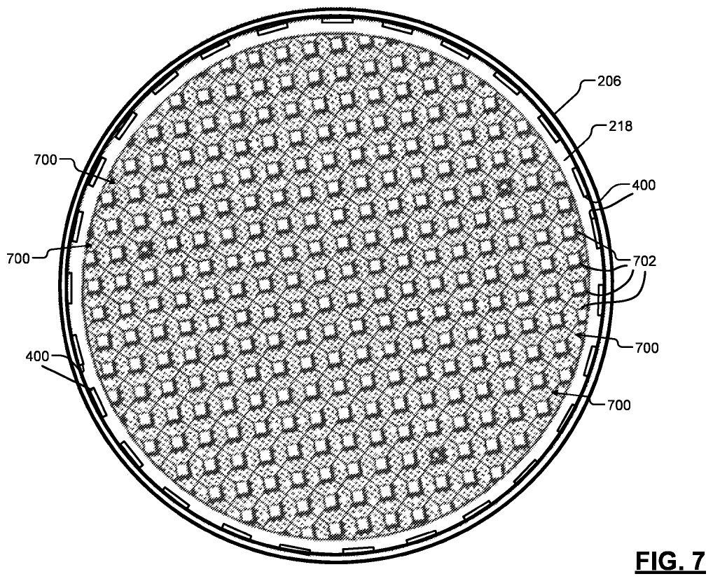

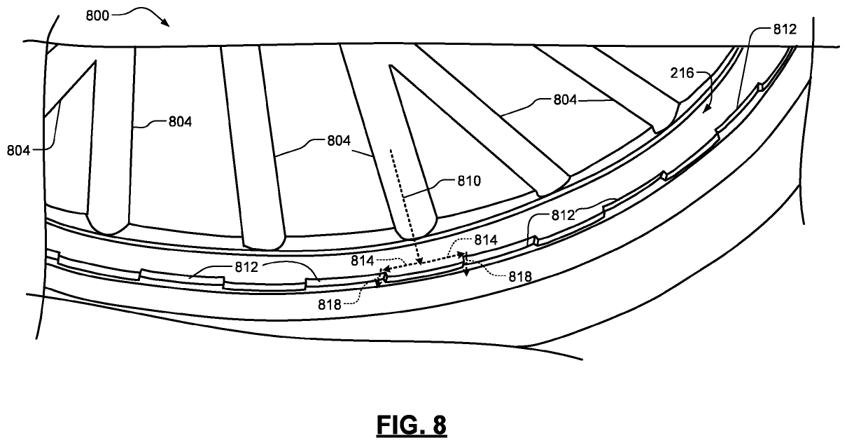

Gas flows radially through the channels to the outermost portion of the first plenum 216, turns and flows annularly towards notches (shown in FIG. 8) of the first plenum 216, turns back and flows annularly inward to get around edges of the notches, then turns again to flow annularly towards areas below inlets of the vertical passages, and then turns up through the vertical passages. The gas flow arrows do not show flow of the gas annularly from locations near edges of the notches to areas below the vertical channels. This causes the gas to make five turns in order to pass through the vertical passages. The gas is directed from the vertical passages to a second plenum 218 in the cross-drilled layer 206, where the gas makes another turn to flow radially inward. The second plenum 218 directs the gas radially inward to cross-drilled passages in the cross-drilled layer 206, which directs the gas upward and out holes 228 in the top layer 208. This directs the gas toward the backside of a substrate. Examples of cross-drilled passages are shown in FIG. 7. The outer walls of the plenums 216, 218 and the vertical passages are defined by one or more outer annular members (one outer annular member 219 is shown).

The pedestal 102 of FIG. 1 and/or the portion 200 of FIG. 2 may include multiple layers and/or plates. In an embodiment, the pedestal 102 and/or the portion 200 are formed as a monoblock. The layers 202, 204, 206, 208 and the outer annular member 219 may be integrally formed as a single part or multiple parts. In one embodiment, the layers 202, 204, 206, 208 are respective stacked plates.

In FIG. 2, the gas channels 210 include an inlet portion 210A and an outlet portion 210B. Gas (or fluid) flow is shown by dashed arrows. The inlet portion 210A extends radially from a vertical supply channel 230 to the outlet portion 210B. The outlet portion 210B is a larger inner diameter than the inlet portion 210A. Although shown as transitioning between two different inner diameters, the channels 210 and/or other channels of the gas distribution layer 202 may transition multiple times between two different inner diameters. The inner diameters increase in size the more radially outward the location at which the inner diameter is measured.

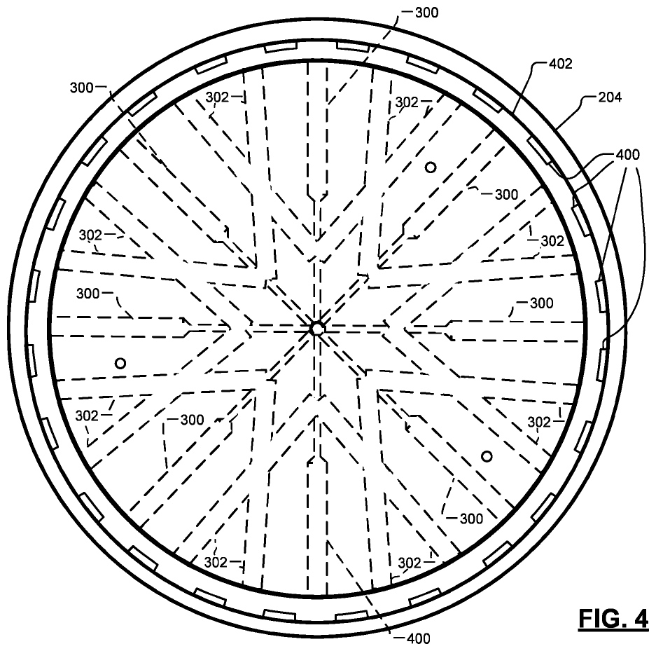

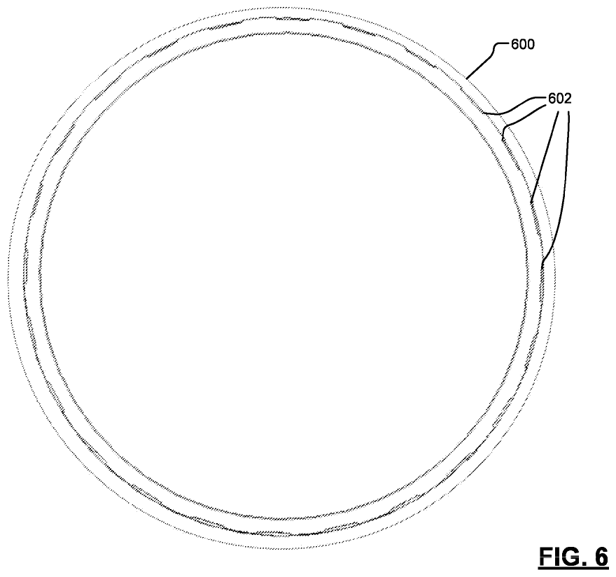

The baffle layer 204 includes the vertical passages (e.g., the passages 212 and others) defined by an inner annular member and an outer annular member (e.g., members 402, 404 of FIG. 4), which are collectively referred to as a baffle. The vertical passages extend vertically and fluidically connect the first plenum 216 and the second plenum 218. Examples of the baffle layer 204 are shown in FIGS. 3 and 6. The cross-drilled layer 206 receives gas from the second plenum 218, which is also ring-shaped. Cross-drill passages in the cross-drilled layer 206 redirect the gas toward the holes 228.

There are four direction changes in gas flow due to the two plenums 216, 218 and two direction changes in gas flow due to the baffle layer 204 and location thereof relative to recesses of the first plenum 216. The arrangement of the plenums 216, 218 and vertical passages (e.g., passages 212) thus provides six direction changes in gas flow and performs as a particle trap. Particles may be trapped, for example, in the first plenum 216, the vertical passages and/or the second plenum 218. Any particles entrained in the gas become trapped in the plenums 216, 218. This prevents particles from being directed out the top layer 208 and at a substrate. This provides a trap for collecting any particles that may have been sourced from the walls of the channels and/or from a source upstream from the channels 210. The plenums 216, 218 and the baffle eliminates any directionality due to the channels upstream from the first plenum 216 and increases uniform gas distribution.

Cross-sectional width W1 of each of the vertical passages (e.g., the passages 212) is less than a cross-sectional width W2 of the second plenum 218. The cross-sectional width W2 is less than a cross-sectional width W3 of the first plenum 216. An outermost wall 240 of each of the vertical passages is radially aligned with an outermost wall 242 of the second plenum 218. The outermost walls 240, 242 are radially inward of a radially outer wall 244 of the first plenum 216. The radially outer wall 244 may have recessed portions (or notches) equally spaced about the radially outermost wall 244 and annularly aligned with outputs of the channels (e.g., channels 210). This is further shown and described with respect to FIG. 8.

Although each of the following examples includes a certain number of main channels, adjacent channels (or branches), spreading junctions, cross-over junctions, and vertical passages, a different number of each may be included.

FIG. 3 shows the gas distribution layer 202, which includes a pattern of gas distribution channels (referred to as “channels”) for distributing gas received via the vertical supply channel 230 to the first plenum 216. In the example shown, eight main channels 300 are shown with first (or inner) portions 300A and second (or outer) portions 300B. Although each of the channels 300 are shown having two portions with different diameters, each of the channels 300 may have more than two portions with different diameters. The inner portions 300A extend from the vertical supply channel 230 to the outer portions 300B, which extend from the inner portions 300A to the first plenum 216. The inner diameters of the outer portions 300B are larger than the inner diameters of the inner portions 300A. As a result, an overall cross-sectional flow area of the main channels 300 increases radially, such that a first overall cross-sectional flow area of inlets of the main channels 300 is less than a second overall cross-sectional flow area of outlets of the main channels 300. The overall cross-sectional flow area of the inlets is a sum of the cross-sectional area of each of the inlets, which is dependent on the inner diameters of the inlets. The overall cross-section flow area of the outlets is a sum of the cross-sectional area of each of the outlets, which is dependent on the inner diameters of the outlets. The outer portions 300B may be referred to as counterbores relative to the inner portions 300A. The gas distribution pattern of the gas distribution layer 202 includes equal spaced apart channels with a symmetric pattern about both X and Y axes.

Each of the main channels 300 divert portions of the gas received to two adjacent channels 302 at a spreading junction 304 along the inner portion 300A. The two adjacent (or outer) channels 302 angle outward from the main (or inner) channel 300 and cross through two other adjacent (or outer) channels 302 at cross-over junctions 306. The cross-over junctions 306 are radially outward of the spreading junctions 304. Portions of the adjacent channels 302 that are radially inward of the cross-over junctions 306 are arranged in a star-shaped pattern having eight radially outer points located respectively at the cross-over junctions 306 and eight radially inner points located respectively at the spreading junctions 304. The inner diameters of the adjacent channels 302 may be the same as inner diameters of the outer portions 300B. The gas distribution layer 202 may include holes 340 for passage of lift pins for lifting a substrate from a corresponding pedestal.

The gas distribution channels 300 (or spokes) have varying and increasing inner diameters. Because of the diverting of some gas to adjacent channels 302, the number of gas distribution channels increases radially. For example, near the vertical supply channel 230 there are eight channels, whereas along the periphery of the gas distribution layer 202 there are twenty-four channels. The increasing inner diameters and the increase in the number of gas distribution channels reduces the exit velocity of gas out of the channels 300, 302. In one embodiment, the exit velocity is reduced by 20% as compared to the gas velocity of gas received by the inner portions 300A of the channels 300. The pattern of spokes is designed for ease in manufacturing. For example, a smaller number of channels (or inlet channels) extend from the vertical supply channel 230 than provide gas to the first plenum 216. A limited number of channels can be disposed around and receive gas from the vertical supply channel 230.

In the example shown, each of the main channels 300 divert some of the gas to a first pair of adjacent channels (outer gas distribution channels) 302 having a first pair of additional outlets. Another pair of additional outlets are provided by a second pair of the adjacent channels 302 that cross through the first pair of adjacent channels 302. As such, each gas flow path from the vertical supply channel 230 to the first plenum 216 includes an inlet at the vertical supply channel 230 and five outlets at the first plenum 216. This aids in equalizing pressures in all of the outer gas distribution channels (or exit channels), referring to the outer portions 300B and the adjacent channels 302.

There is a reduced number of channels connected to and directly receiving gas from vertical supply channel 230 as compared to a gas distribution layer having eight spokes extending radially from a vertical supply channel to an outer periphery of the gas distribution layer. The main channels 300 may each have varying inner diameters that gradually increase from the vertical supply channel 230 to the first plenum 216.

The outer portions 300B are radially outward of the spreading junctions 304. The outer portions 300B are disposed annularly between two of the adjacent channels 302. There are twice as many adjacent channels 302 as there are outer portions 300B. The inner portions 300A extend radially outward to the spreading junctions and then from there radially outward to the outer portions 300B. As shown, the eight cross-over junctions 306 are radially outward of the eight spreading junctions 304.

In one embodiment, the flow rates out of the output channels (e.g., the outer portions 300B, and the channels 302 are the same or within a predetermined range (e.g., 0-3%) of each other. In another embodiment, the flow rates out of the outer portions 300B are the same or within a predetermined range (e.g., 0-3%) of each other. In an embodiment, the flow rates out of the channels 302 are the same or within a first predetermined range (e.g., 0-3%) of each other and different from the flow rates out of the outer portions 300B, which may be within a second predetermined range of each other (e.g., 0-3%). In one embodiment, the flow rates out of the outer portions 300B are 1-5 times more than the flow rates out of the channels 302. The flow rates may refer to volumetric flow rates or mass flow rates.

FIG. 4 shows an example of the baffle layer 204 of FIG. 2. The baffle layer 204 is shown above the gas distribution layer 202 of FIG. 2 having the pattern of gas distribution channels 300, 302, which are shown by dashed hidden lines. The baffle layer 204 includes vertical passages (some of which are designated 400), which include the vertical passages 212 of FIG. 2. The vertical passages are: located radially outward of the channels 300, 302 of the gas distribution layer 202; defined by inner annular member 402 and outer annular member 404; and offset annularly from outlets of the channels 300, 302, such that gas needs to turn from flowing in a radial direction to flowing in an annular direction to pass through the vertical passages.

FIG. 5 shows another example gas distribution layer 500 that is similar to the gas distribution layer 202 of FIG. 3, but having different length channels and portions thereof and different angles between adjacent channels. The diameter of the gas distribution layer 500 may be the same or different than the diameter of the gas distribution layer 202 of FIG. 3.

The gas distribution layer 500 includes a pattern of gas distribution channels (also referred to as “channels”) for distributing gas received via the vertical supply channel 501 to a first plenum 503. In the example shown, eight main channels 504 are shown with first (or inner) portions 504A and second (or outer) portions 504B. The inner portions 504A extend from the vertical supply channel 501 to the outer portions 504B, which extend from the inner portions 504A to the first plenum 503. The inner diameters of the outer portions 504B are larger than the inner diameters of the inner portions 504A. As a result, an overall cross-sectional flow area of the main channels 504 increases radially, such that a first overall cross-sectional flow area of inlets of the main channels 504 is less than a second overall cross-sectional flow area of outlets of the main channels 504. The overall cross-sectional flow area of the inlets is a sum of the cross-sectional area of each of the inlets, which is dependent on the inner diameters of the inlets. The overall cross-section flow area of the outlets is a sum of the cross-sectional area of each of the outlets, which is dependent on the inner diameters of the outlets. The outer portions 504B may be referred to as counterbores relative to the inner portions 504A. The gas distribution pattern of the gas distribution layer 500 includes equal spaced apart channels with a symmetric pattern about both X and Y axes.

Each of the main channels 504 divert portions of the gas received to two adjacent channels 506 at a spreading junction 508 along the inner portion 504A. The two adjacent (or outer) channels 506 angle outward from the main (or inner) channel 504 and cross through two other adjacent (or outer) channels 506 at cross-over junctions 510. The cross-over junctions 510 are radially outward of the spreading junctions 508. Portions of the adjacent channels 506 that are radially inward of the cross-over junctions 510 are arranged in a star-shaped pattern having eight points located at the cross-over junctions 510. The inner diameters of the adjacent channels 506 may be the same as inner diameters of the outer portions 504B. The gas distribution layer 500 may include holes (not shown) for passage of lift pins for lift a substrate from a corresponding pedestal.

The gas distribution channels 504 (or spokes) have varying and increasing inner diameters. Because of the diverting of some gas to adjacent channels 506, the number of gas distribution channels increases radially. For example, near the vertical supply channel 501 there are eight channels, whereas along the periphery of the gas distribution layer 500 there are twenty-four channels. The increasing inner diameters and the increase in the number of gas distribution channels reduces the exit velocity of gas out of the channels 504, 506. The pattern of spokes is designed for ease in manufacturing. For example, a smaller number of channels (or inlet channels) extend from the vertical supply channel 501 than provide gas to the first plenum 503. A limited number of channels can be disposed around and receive gas from the vertical supply channel 501.

In the example shown, each of the main channels 504 diverts some of the gas to a first pair of adjacent channels (outer gas distribution channels) 506 having a first pair of additional outlets. Another pair of additional outlets are provided by a second pair of the adjacent channels 506 that cross through the first pair of adjacent channels 506. As such, each gas flow path from the vertical supply channel 501 to the first plenum 503 includes an inlet at the vertical supply channel 501 and five outlets at the first plenum 503. This aids in equalizing pressures in all of the outer gas distribution channels (or exit channels), referring to the outer portions 504B and the adjacent channels 506.

There is a reduced number of channels connected to and directly receiving gas from vertical supply channel 501 as compared to a gas distribution layer having eight spokes extending radially from a vertical supply channel to an outer periphery of the gas distribution layer. The main channels 504 may each have varying inner diameters that gradually increase from the vertical supply channel 501 to the first plenum 503.

The outer portions 504B are radially outward of the spreading junctions 508. The outer portions 504B are disposed annularly between two of the adjacent channels 506. There are twice as many adjacent channels 506 as there are outer portions 504B. The inner portions 504A extend radially outward to the spreading junctions and then from there radially outward to the outer portions 504B. As shown, the eight cross-over junctions 510 are radially outward of the eight spreading junctions 508.

In one embodiment, the flow rates out of the output channels (e.g., the outer portions 504B, and the channels 506 are the same or within a predetermined range of each other. In another embodiment, the flow rates out of the outer portions 504B are the same or within a predetermined range of each other. In an embodiment, the flow rates out of the channels 506 are the same or within a predetermined range of each other and different from the flow rates out of the outer portions 504B.

In one embodiment, the flow rates out of the output channels (e.g., the outer portions 504B, and the channels 506 are the same or within a predetermined range (e.g., 0-50%) of each other. In another embodiment, the flow rates out of the outer portions 504B are the same or within a predetermined range (e.g., 0-5%) of each other. In an embodiment, the flow rates out of the channels 506 are the same or within a first predetermined range (e.g., 0-5%) of each other and different from the flow rates out of the outer portions 504B, which may be within a second predetermined range of each other (e.g., 0-5%). In one embodiment, the flow rates out of the outer portions 504B are 1-5 times more than the flow rates out of the channels 506. The flow rates may refer to volumetric flow rates or mass flow rates.

FIG. 6 shows another baffle layer 600 corresponding to the gas distribution layer 500 of FIG. 5. The baffle layer 600 includes vertical passages (some of which are designated 602). The vertical passages are located radially outward of the channels 504, 506 of the gas distribution layer 500 of FIG. 5 and offset annularly from outlets of the channels 504, 506, such that gas needs to turn from flowing in a radial direction to flowing in an annular direction to pass through the vertical passages.

FIG. 7 shows an example of the cross-drilled layer 206 of the gas distribution pedestal 102 of FIGS. 1-2. The cross-drilled layer 206 includes passages (some of which designated 700) that are fluidically coupled and direct gas received from the second plenum 218 to the holes 228 in the top layer 208 of FIG. 2. The passages are created by multiple posts (some of which designated 702) that are uniformly distributed across the cross-drilled layer 206. Gas flows around the posts and then up and out through the holes 228. The posts are offset laterally from the holes 228. The plenum 218 receives gas from the vertical passage 400 of FIG. 4.

FIG. 8 shows portion 800 of the example gas distribution layer 202 of FIG. 2. The portion 800 includes spokes 804 (e.g., the channels 300, 302 of FIG. 3) that radially output gas to the first plenum 216, represented by arrow 810. The outer wall 244 of the plenum 216 includes recesses (or notches) 812 that are annularly in alignment with outputs of the spokes 804. The gas flow to the recesses 812, turns and flows around the annular outer edges of the recesses 812 of the corresponding baffle, as represented by arrows 814. The gas then changes direction and is directed up and out of the vertical passages (e.g., passages 212 and 400 of FIGS. 2 and 4) to a second plenum (example of which shown in FIGS. 2 and 7) above the baffle layer, as represented by arrows 818.

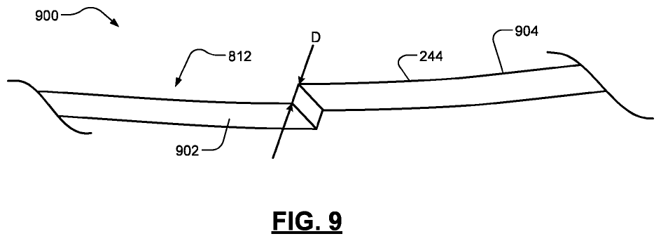

FIG. 9 shows a portion 900 of the outer wall 244 of the first plenum 216 of FIG. 2 illustrating radial depth D of one of the recesses 812. The depth D is a distance from an outermost walls 902 of the recesses 812 to non-recessed wall portions 904 of the outer wall 244 of the first plenum 216. The non-recessed wall portions 904 are radially align with the outermost wall of the vertical passages (e.g., outermost walls 240 of passages 212, 400 of FIGS. 2 and 4) of the baffle layer 204 of FIG. 2.

FIG. 10 shows a processing chamber 1000 including a showerhead 1002 and a pedestal 1004. The showerhead 1002 includes layers 1006 for gas distribution. The layers 1006 are configured similarly as the layers 103 of the pedestal 102 of FIG. 1, but are in an upside down configuration to direct gas to a top side of a substrate. The showerhead 1002 receives gas as described above for the showerhead 124 of FIG. 1. An example of the layers 103 is shown in FIG. 10. The pedestal 1004 supports a substrate 1010 that is positioned below the showerhead 1002.

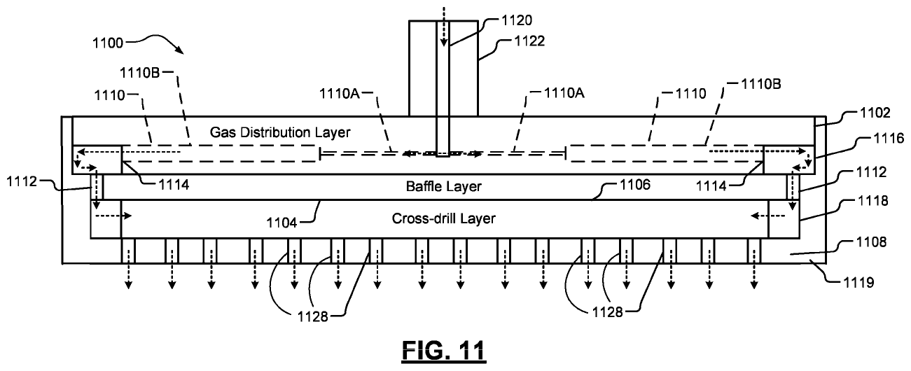

FIG. 11 shows a portion 1100 of the showerhead 1002 of FIG. 10. The portion 1100 includes a gas distribution layer 1102, a baffle layer 1104, a cross-drilled layer 1106, and a bottom layer (or faceplate) 1108. The gas distribution layer 1102 has a pattern of gas distribution channels (also referred to as “spokes”), some of which (designated channels 1110) are shown with dashed lines to illustrate gas flow. The channels 1110 are not annularly in line with vertical gas passages (two example passages 1112 are shown in FIG. 11) in the baffle layer 1104. The channels 1110 and passages 1112 may be arranged and configured similarly as the channels and passages of FIGS. 2-6.

The gas distribution layer 1102 includes a pattern of gas distribution channels, examples of which are shown in FIGS. 3 and 5. The gas distribution channels have radially decreasing flow velocities due to: increases in inner diameters of the channels; increases in the number of channels; and spreading of gas from a smaller number of channels to a larger number of channels. The structure of the gas distribution layer 1102 equalizes pressures in the channels and uniformly distributes gas to outlets (e.g., outlets 1114) of the channels. The outlets of the channels output gas to a first plenum 1116. The plenum 1116 is ring-shaped and distributes the gas to vertical passages (e.g., the passages 1112) of the baffle layer 1104. The vertical passages (also referred toas channels) are offset radially inward from an outermost portion (or recessed walls) of the first plenum 1116 and offset annularly from the outlets of the channels.

Gas flows radially through the channels to the outermost portion of the first plenum 1116, turns and flows annularly towards notches of the first plenum 1116, turns back and flows annularly inward to get around edges of the notches, then turns again to flow annularly towards areas below inlets of the vertical passages, and then turns down through the vertical passages. The gas flow arrows do not show flow of the gas annularly from locations near edges of the notches to areas above the vertical channels. This causes the gas to make five turns in order to pass through the vertical passages. The gas is directed from the vertical passages to a second plenum 1118 in the cross-drilled layer 1106. The second plenum 1118 directs the gas radially inward to cross-drilled passages in the cross-drilled layer 1106, which directs the gas downward and out holes 1128 in the bottom layer 1108. This directs the gas toward the top side of a substrate. Examples of cross-drilled passages are shown in FIG. 7. The outer walls of the plenums 1116, 1118 and the vertical passages are defined by one or more outer annular members (one outer annular member 1119 is shown). The outer annular member 1119 may have a unitary structure or be formed of multiple annular members.

The showerhead 1002 of FIG. 10 and/or the portion 1100 of FIG. 11 may include multiple layers and/or plates. In an embodiment, the showerhead 1002 and/or the portion 1100 are formed as a monoblock. The layers 1102, 1104, 1106, 1108 and the outer annular member 219 may be integrally formed as a single part or multiple parts. In one embodiment, the layers 1102, 1104, 1106, 1108 are respective stacked plates.

In FIG. 11, the gas channels 1110 include an inlet portion 1110A and an outlet portion 1110B. The inlet portion 1110A extends radially from a vertical supply channel 1120 to the outlet portion 1110B. The vertical supply channel 1120 extends through a stem 1122 of the showerhead and into the gas distribution layer 1102. The outlet portion 1110B has a larger inner diameter than the inlet portion 1110A. Although shown as transitioning between two different inner diameters, the channels 1110 and/or other channels of the gas distribution layer 1102 may transition multiple times between two different inner diameters. The inner diameters increase in size the more radially outward the location at which the inner diameter is measured.

The baffle layer 1104 includes the vertical passages (e.g., the passages 1112 and others) and inner and outer annular members (e.g., the annular members 402 and 404 of FIG. 4), which are collectively referred to as a baffle. The vertical passages extend vertically and fluidically connect the first plenum 1116 and the second plenum 1118. Examples of the baffle layer 1104 are shown in FIGS. 3 and 6. The cross-drilled layer 1106 receives gas from the second plenum 1118, which is also ring-shaped. Cross-drill passages in the cross-drilled layer redirect the gas toward the holes 1128.

There are four direction changes in gas flow due to the two plenums 1116, 1118 and two direction changes in gas flow due to the baffle layer 1104 and location thereof relative to recesses of the first plenum 1116. The arrangement of the plenums 1116, 1118 and vertical passages (e.g., passages 1112) thus provides six direction changes in gas flow and performs as a particle trap. Particles may be trapped, for example, in the first plenum 1116, the vertical passages and/or the second plenum 1118. Any particles entrained in the gas become trapped in the plenums 1116, 1118. This prevents particles from being directed out the bottom layer 1108 and at a substrate. This provides a trap for collecting any particles that may have been sourced from the walls of the channels and/or from a source upstream from the channels. The plenums 1116, 118 and the baffle eliminate any directionality and increases uniform gas distribution.

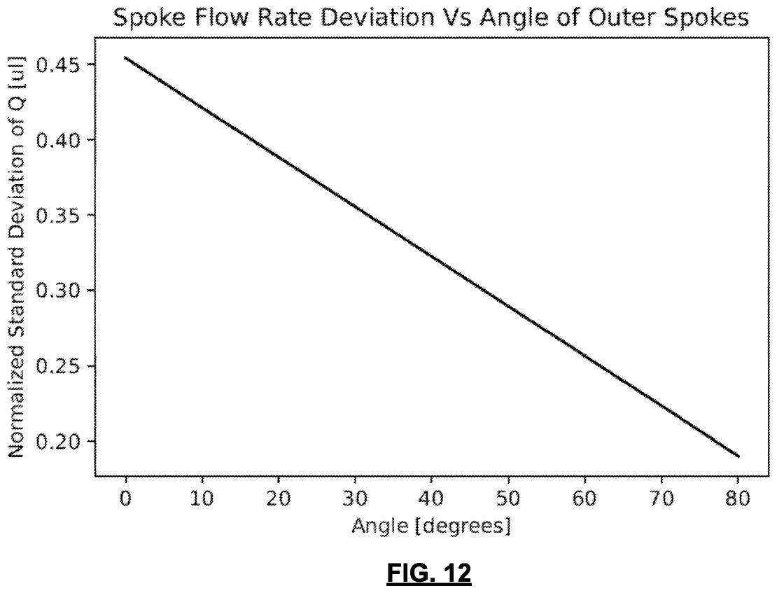

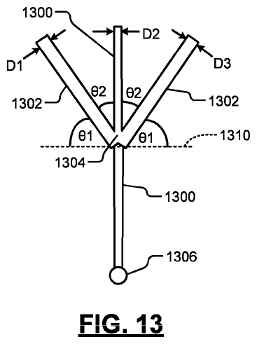

FIG. 12 shows a plot of normalized standard deviation (STD) of volumetric flow rate Q versus angle θ1 between inner and outer spokes of a gas distribution layer. The normalized STD of volumetric flow rate Q is unitless (μl). FIG. 13 shows an example inner (main) spoke 1300 and example outer (adjacent) spokes 1302 of a gas distribution layer. This is representative of other inner and outer spoke arrangements of the examples of FIGS. 3 and 5. The outer spokes 1302 extend adjacent the inner spoke 1300. The arrangement shown includes a spreading junction 1304. The inner spoke 1300 diverts some gas received from a vertical supply channel 1306 to the adjacent spokes 1302. This is a similar arrangement as, for example, the main channels 300 and adjacent channels 302 of FIG. 3 and the main channels 504 and adjacent channel 506 of FIG. 5. The angle θ1 is the angle between each of the adjacent (or outer) channels 1302 and a line 1310, which extends perpendicular to the inner channel 1300. The angle θ2 is an angle between each of the outer channels 1302 and the inner channel 1300. Inner diameters of the inner and outer channels 1300, 1302 are designated D1, D2, D3.

The normalized volumetric flow rate is a function of the angle θ1. Increasing the angle θ1 creates more parallel flow paths and as a result improves balance of flow between each spoke. Increasing the θ1 decreases the flow imbalance among the inner and outer channels, as shown by the plot of FIG. 12. As an example, θ1 may be 45°-60°. In one embodiment, θ1 is 50°-55°.

Normalized volumetric flow rate Q_{n,normalized} is equal to the flow rate Qₙ through a channel divided by the flow rate Qᵢₙₙₑᵣ through the inner channel 1300 in the portion between the outer channels 1302. As an example, a normalized volumetric flow rate Q_{n,normalized} may be determined for each of the channels 1300, 1302. The standard deviation may be in terms of percentage. If the flow rate for the inner channel 1300 is, for example, 1 (because it was divided by itself), and the flow rate through the outer channels 1302 is 0.34, then the outer flow rate is 34% of the flow rate of the inner channel. This allows the flow rates of channels of a gas distribution layer to be compared.

As an example, if for a first test, the volumetric flow rate for the inner channel 1300 is 3.53×10⁻5 meters cubed per second (m³/s) and the flow rate of each of the outer channels 1302 is 1.28×10⁻⁶ m³/s then if for a second test the flow rate of the inner channel 1300 is 4.38×10⁻⁵ m³/s and the flow rate of each of the outer channels 1302 is 9.63×10⁻⁶ m³/s, it would be challenging to compare the two tests. Instead, by normalizing the flow rates, the first test had a normalized volumetric flow rate Q_{n,normalized} for the inner channel 1300 of 1 and a normalized volumetric flow rate Q_{n,normalized} for each of the outer channels 1302 of 36% of the flow rate of the inner channel (0.36) and the second test had a normalized volumetric flow rate Q_{n,normalized} for the inner channel 1300 of 1 and a normalized volumetric flow rate Q_{n,normalized} for each of the outer channels 1302 of 22% of the flow rate of the inner channel 1300 (0.22) and now the two tests are able to be directly compared.

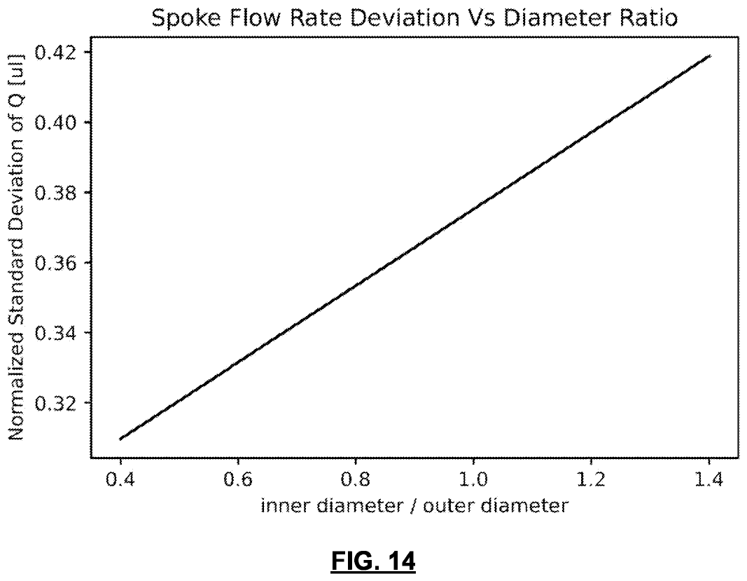

FIG. 14 shows a plot of normalized STD of volumetric flow rate versus an inner diameter ratio of inner and outer spokes. Referring to FIGS. 13 and 14, the inner diameter ratio refers to the inner diameter D2 of the inner spoke divided by the inner diameter D1 or D3 of an outer spoke. The inner diameter D1 may be equal to the inner diameter D3. Normalized volumetric flow rate is a function of the inner diameter ratio. Increasing the inner diameter of the inner channel (or equivalently decreasing the inner diameter of the outer channel), increases flow imbalance among the inner and outer channels. Increasing the inner diameter of the inner channel or decreasing the inner diameter of the outer channels increases the flow imbalance among the inner and outer channels.

Normalized volumetric flow rates at outlets of main channels of a gas distribution layer may be the same or within a predetermined percentage (0-3%) of each other. Normalized volumetric flow rates of outlets of adjacent channels (or branches of main channels) may be the same or within a predetermined percentage (0-3%) of each other. Normalized volumetric flow rates of outlets of each of the main channels and outlets of each of the branches may be the same or within a predetermined percentage (0-3%) of each other

The examples described above provide channel patterns with geometries for minimizing exit velocities of gas out of the channels and to an outer peripheral plenum. This provides a balanced flow of gas throughout gas distribution layers of a pedestal and/or showerhead structure. The examples also include particle traps to minimize and/or prevent damage to a substrate due to entraining of particles upstream of the plenum.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Although the terms first, second, third, etc. may be used herein to describe various elements, layers, channels, spreading junctions, cross-over junctions, components, and/or devices, these elements, layers, channels, spreading junctions, cross-over junctions, components, and/or devices should not be limited by these terms, unless otherwise indicated. These terms may be only used to distinguish one element, layer, channel, spreading junction, cross-over junction, component, and/or device from another element, layer, channel, spreading junction, cross-over junction, component, and/or device. Terms such as “first,” “second,” and other numerical terms when used herein do not imply a sequence or order unless clearly indicated by the context. Thus, a first element, layer, channel, spreading junction, cross-over junction, component, and/or device could be termed a second element, layer, channel, spreading junction, cross-over junction, component, and/or device without departing from the teachings of the example embodiments.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A pedestal comprising:
a support shaft comprising a supply channel configured to receive a process fluid; and
a body comprising a plurality of layers configured to receive the process fluid from the supply channel and distribute the process fluid across the body and direct the process fluid from the pedestal at a substrate being processed, the body comprising
a distribution layer comprising
a first plenum, and
a plurality of channels extending radially from the supply channel to the first plenum and supplying the process fluid from the supply channel to the first plenum,
a baffle layer comprising a first plurality of passages extending from the first plenum to a second plenum, and
a cross-drill layer comprising a second plurality of passages and the second plenum,
wherein the first plenum, the first plurality of passages, and the second plenum are configured to at least one of i) trap particles, and ii) increase flow rate uniformity of the process fluid to the second plurality of passages.

2. The pedestal of claim 1, wherein:
the first plenum is ring-shaped;
the first plurality of passages extend vertically from the first plenum to the second plenum; and
the second plenum is ring-shaped.

3. The pedestal of claim 1, wherein the first plurality of passages are radially inward of a radially outermost wall of the first plenum.

4. The pedestal of claim 1, wherein the first plenum comprises a plurality of recesses annularly in alignment with outlets of the plurality of channels.

5. The pedestal of claim 4, wherein:
the plurality of channels comprise a plurality of main channels and a plurality of branches extending from the plurality of main channels to the first plenum; and
outlets of the plurality of main channels and outlets of the plurality of branches are annularly in alignment respectively with the plurality of recesses.

6. The pedestal of claim 1, wherein a cross-sectional width of each of the first plurality of passages, measured radially, is smaller than a radially width of the first plenum and a radial width of the second plenum, which are also measured radially.

7. The pedestal of claim 1, wherein the first plurality of passages are annularly offset from outputs of the plurality of channels.

8. The pedestal of claim 1, wherein the process fluid changes flow direction six times subsequent to exiting the plurality of channels and prior to exiting the second plenum.

9. The pedestal of claim 1, wherein the cross-drill layer comprises the second plurality of passages configured to receive the process fluid from the second plenum.

10. The pedestal of claim 1, wherein:
the first plurality of passages extend vertically; and
the second plurality of passages extend horizontally across the cross-drill layer.

11. The pedestal of claim 1, wherein:
the first plenum changes flow direction of the process fluid multiple times; and
the baffle layer changes flow direction of the process fluid multiple times.

12. The pedestal of claim 1, wherein:
radially outermost walls of the first plurality of passages are laterally aligned with an outermost wall of the second plenum; and
radially outermost wall of the first plenum is radially outward of the outermost wall of the second plenum and the outermost walls of the first plurality of passages.

13. The pedestal of claim 1, wherein the distribution layer comprises:
a pair of channels that extend from each of the plurality of channels to the first plenum; and
a total number of the first plurality of passages is equal to a sum of a total number of outputs of the plurality of channels and a total number of outputs of the pairs of channels that extend from each of the plurality of channels.

14. The pedestal of claim 1, wherein each respective channel of the plurality of channels is configured to decrease flow velocity radially along the respective channel, such that a first flow velocity at an inlet of the respective channel is greater than a second flow velocity at an outlet of the respective channel.

15. A showerhead comprising:
a stem comprising a supply channel configured to receive a process fluid; and
a body comprising a plurality of layers configured to receive the process fluid from the supply channel and distribute the process fluid across the body and direct the process fluid from the showerhead at a substrate being processed, the body comprising
a distribution layer comprising
a first plenum, and
a plurality of channels extending radially from the supply channel to the first plenum and supplying the process fluid from the supply channel to the first plenum,
a baffle layer comprising a first plurality of passages extending from the first plenum to a second plenum, and
a cross-drill layer comprising a second plurality of passages and the second plenum,
wherein the first plenum, the first plurality of passages, and the second plenum are configured to at least one of i) trap particles, and ii) increase flow rate uniformity of the process fluid to the second plurality of passages.

16. The showerhead of claim 15, wherein:
the first plenum is ring-shaped;
the first plurality of passages extend vertically from the first plenum to the second plenum; and
the second plenum is ring-shaped.

17. The showerhead of claim 15, wherein the first plurality of passages are radially inward of a radially outermost wall of the first plenum.

18. The pedestal of claim 15, wherein the first plenum comprises a plurality of recesses annularly in alignment with outlets of the plurality of channels.

19. The pedestal of claim 18, wherein:
the plurality of channels comprise a plurality of main channels and a plurality of branches extending from the plurality of main channels to the first plenum; and
outlets of the plurality of main channels and outlets of the plurality of branches are annularly in alignment respectively with the plurality of recesses.

20. The showerhead of claim 15, wherein a cross-sectional width of each of the first plurality of passages, measured radially, is smaller than a radially width of the first plenum and a radial with of the second plenum, which are also measured radially.

21. The showerhead of claim 15, wherein the first plurality of passages are annularly offset from outputs of the plurality of channels.

22. The showerhead of claim 15, wherein the process fluid changes flow direction six times subsequent to exiting the plurality of channels and prior to exiting the second plenum.

23. The showerhead of claim 15, wherein the cross-drill layer comprises the second plurality of passages configured to receive the process fluid from the second plenum.

24. The showerhead of claim 15, wherein:
the first plurality of passages extend vertically; and
the second plurality of passages extend horizontally across the cross-drill layer.

25. The showerhead of claim 15, wherein:
the first plenum changes flow direction of the process fluid multiple times; and
the baffle layer changes flow direction of the process fluid multiple times.

26. The showerhead of claim 15, wherein:
radially outermost walls of the first plurality of passages are laterally aligned with an outermost wall of the second plenum; and
radially outermost wall of the first plenum is radially outward of the outermost wall of the second plenum and the outermost walls of the first plurality of passages.

27. The showerhead of claim 15, wherein the distribution layer comprises:
a pair of channels that extend from each of the plurality of channels to the first plenum; and
a total number of the first plurality of passages is equal to a sum of a total number of outputs of the plurality of channels and a total number of outputs of the pairs of channels that extend from each of the plurality of channels.

28. The showerhead of claim 15, wherein each respective channel of the plurality of channels is configured to decrease flow velocity radially along the respective channel, such that a first flow velocity at an inlet of the respective channel is greater than a second flow velocity at an outlet of the respective channel.
